(19) United States
(12) Patent Application Publication
(10) Pub. No.: US 2011/0069434 A1
(43) Pub. Date: Mar. 24, 2011

(54) REMOTE METER READING DEVICE

(75) Inventors: Denis Guillot-Jerome, Buellas (FR); Frederic Droin, Liergues (FR); Tarek Bouzid, Macon (FR)

(73) Assignee: ACTARIS S.A.S., Boulogne-Billancourt (FR)

(21) Appl. No.: 12/935,648

(22) PCT Filed: Mar. 19, 2009
(86) PCT No.: PCT/EP09/53250

§ 371 Date: Dec. 6, 2010

(30) Foreign Application Priority Data
Apr. 2, 2008 (EP) EP 08305078.1

(51) Int. Cl. H05K 5/00

(52) U.S. Cl. 361/679.01

(57) ABSTRACT

The invention relates to a remote-reading device (3) for enabling the consumption of a meter to be read remotely and including a casing with a front wall (3A) and a side wall (3B).

In the invention, the device also includes a specific solar radiation protective cover (4), said cover being disposed on the casing of the remote-reading device and including at least one covering wall (4A) for covering said front wall, the cover being secured to the casing of the remote-reading device.

The device may be a remote-reading module (3) that is installed on a meter, or a remote-transmission relay (10).

The invention relates to a remote-reading device for a meter.

Currently, meters are often associated with a remote-reading module for remotely reading consumption, which module is installed on a pre-installed meter. In order to do this, a reception cavity may be provided, formed in the top face of the cover of the counter, with the module being placed precisely therein, so as to ensure precise positioning of the module's reader arrangement relative to an internal arrangement of the counter, e.g. the indicator disk, thereby ensuring detection of consumption. Detection may be performed in optical, capacitive, inductive, or other manner, e.g. by observing the movement of the indicator disk.

Data may also be transmitted remotely by means of relays disposed between the meter and the control station.

The meters and the relays may be installed outdoors and may be exposed to solar radiation.

These remote-reading devices, modules and relays, contain, within a casing, a certain number of electronic components that are powered by one or more batteries, and the operation thereof may be disturbed by temperature and their lifetime may be reduced.

The invention proposes solving this technical problem by fitting such remote-reading devices with a protective cover.

The invention thus relates to a remote-reading device for enabling the consumption of a meter to be read remotely and including a casing with a front wall and a side wall, the device being characterized in that it also includes a specific solar radiation protective cover, said cover being disposed on the casing of the remote-reading device and including at least one covering wall for covering said front wall, the cover being secured to the casing of the remote-reading device.

The invention makes it possible to increase the lifetime of remote-reading devices that are exposed to the sun.

It also makes it possible to use standard components, essentially standard electronic components and batteries, in order to make up the remote-reading device, and avoid requiring components that can withstand high temperatures.

In a preferred embodiment, said cover includes air-flow means for enabling air to flow between said remote-reading device and said cover.

Said flow of air is advantageously natural.

Said cover preferably includes orifices in said covering wall.

By way of example, the orifices may be slots.

The orifices block light radiation from the sun and place the module in the shade while enabling air to flow.

Preferably, said cover also includes a peripheral rim that may cover the side wall of said remote-reading device, at least in part.

Advantageously, the covering wall and said rim are spaced apart from said front wall and from said side wall respectively of the remote-reading device, the cover being disposed on the device.

In a variant, said peripheral rim may co-operate with an outwardly-directed peripheral flange that is carried by the device, the cover being disposed on the device.

Said cover may be secured to the remote-reading device.

The cover may be secured in the field on a meter that has been pre-mounted and pre-fitted with a module or on a relay, or it may be secured on the module or relay in the factory.

Preferably, said cover is clipped onto the remote-reading device.

Said cover may be hinged onto the remote-reading device, so as to be capable of being raised.

The invention also provides a remote-reading module as mentioned above and that is installed on a meter.

Finally, the invention provides a remote-transmission relay as mentioned above.

The invention is described in greater detail below with reference to the figures which merely show preferred embodiments of the invention.

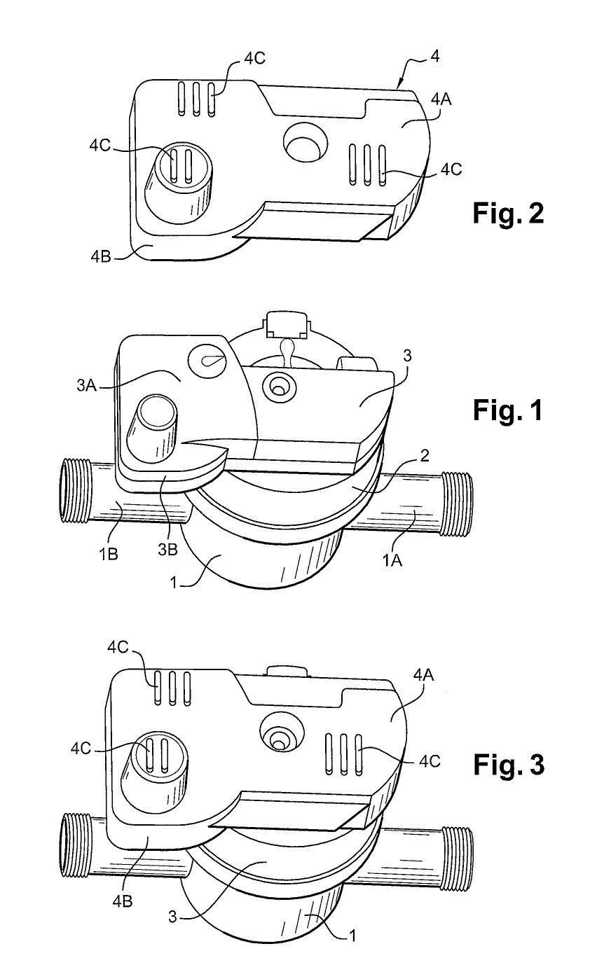

FIG. 1 is a perspective view of a meter fitted with a remote-reading module of a first type.

FIG. 2 is a perspective view of a cover in a first embodiment of the invention.

FIG. 3 is a perspective view of the meter fitted with a remote-reading module and with a cover in this first embodiment of the invention.

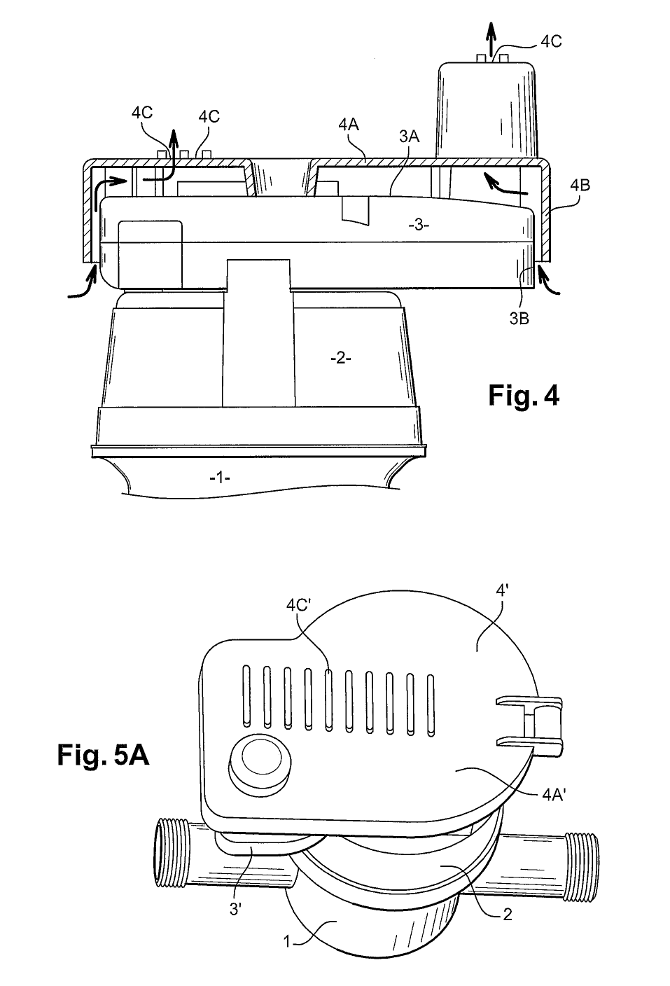

FIG. 4 is a section view of the meter fitted with a remote-reading module and with a cover in this first embodiment of the invention.

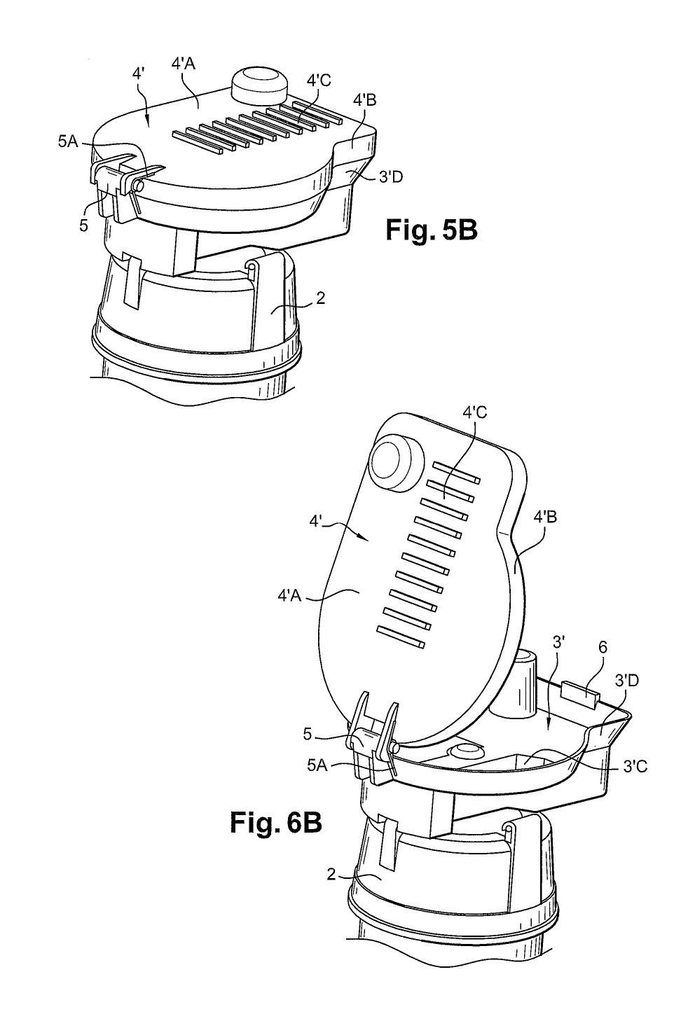

FIGS. 5A and 5B are perspective views of a meter fitted with a remote-reading module of a second type and with a cover in a second embodiment of the invention.

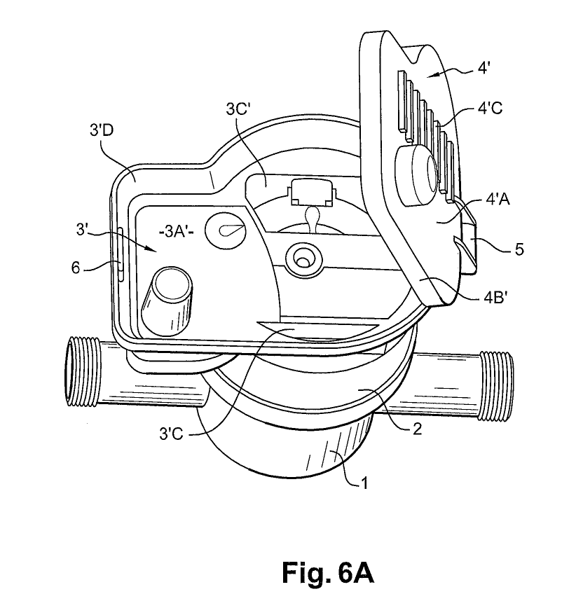

FIGS. 6A and 6B are perspective views of the meter fitted with a remote-reading module and with a cover in this second embodiment of the invention, the cover being raised.

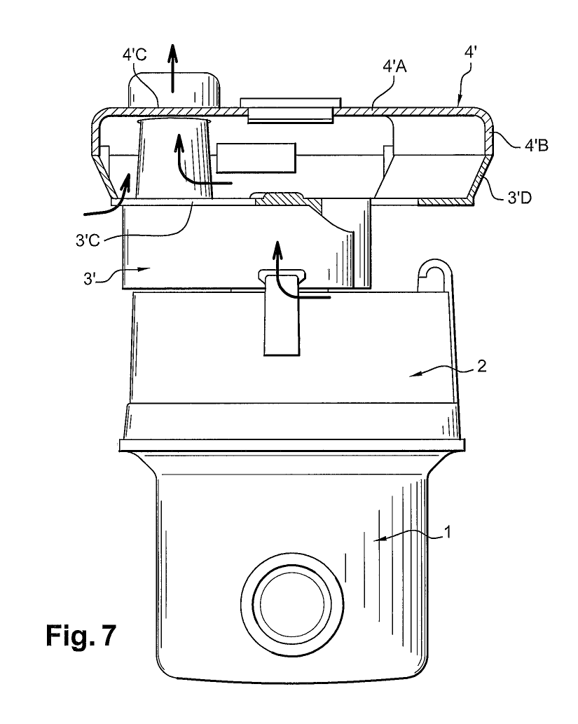

FIG. 7 is a section view of the meter fitted with a remote-reading module and with a cover in this second embodiment of the invention.

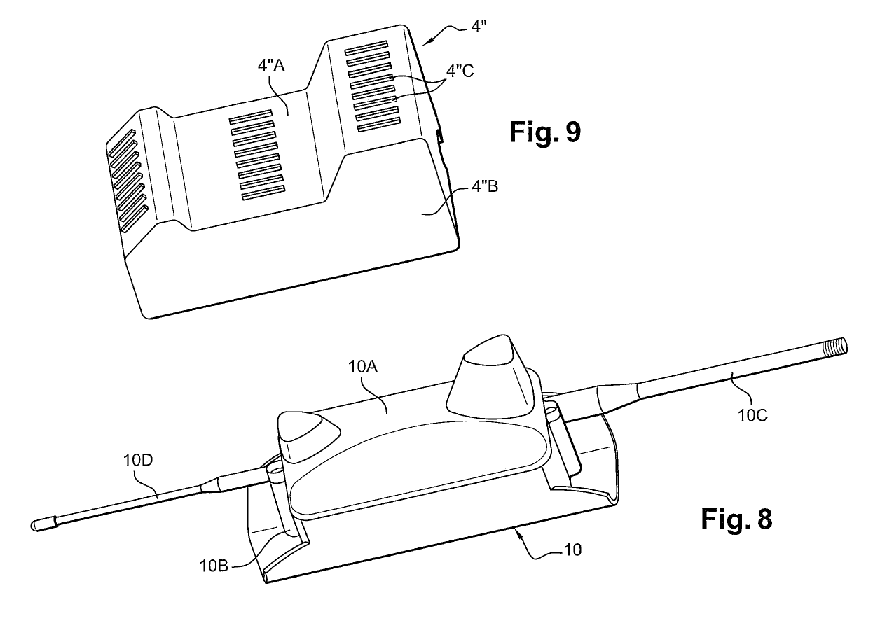

FIG. 8 is a perspective view of a relay for remotely reading the consumption of a meter.

FIG. 9 is a perspective view of a cover in the first embodiment of the invention.

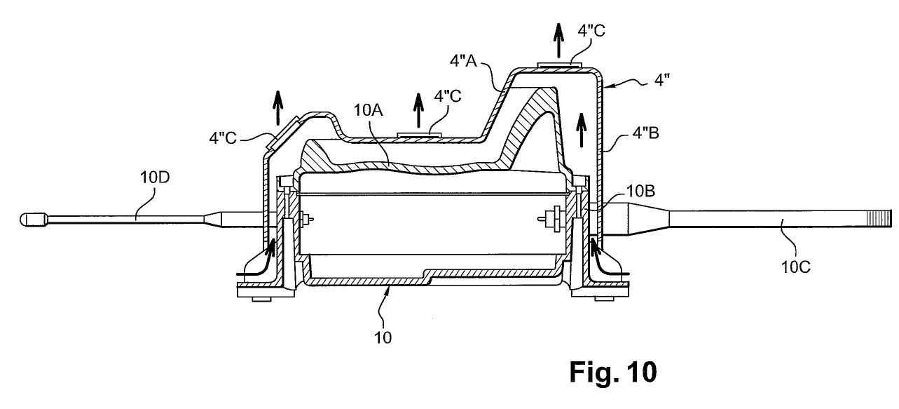

FIG. 10 is a section view of the relay fitted with a cover in the first embodiment of the invention.

FIGS. 1 to 4 show a first embodiment of the invention.

FIG. 1 shows a fluid meter, more precisely a water meter, comprising a vessel 1 provided with a water inlet duct segment 1A and with a water outlet duct segment 1B, and containing a measuring chamber, e.g. having a spinner or a reciprocating piston, and a counter 2 for counting consumption. On the top or front face of the counter there is mounted a remote-reading module 3 that includes a front wall 3A and a side wall 3B, which module is for remotely reading consumption, e.g. by detecting the movement of the indicator disk of the counter in optical, capacitive, inductive, or other manner.

The module covers the top face of the counter 2 only in part, and leaves visible and readable, information that is carried by the top face of the counter 2, such as a specification bar code and the consumption data of a display.

The invention relates to protecting the module 3.

In order to do this, a specific solar radiation protective cover 4 is used, as shown in FIG. 2.

The cover 4 is disposed on the casing of the module 3 and is secured thereto, as shown in FIG. 3, and includes a covering wall 4A for covering the front wall 3A of the module, and a peripheral rim 4B for covering the side wall 3B of the module, at least in part.

In its covering wall 4A, the cover includes slots 4C that constitute air-flow means for enabling air to flow naturally between the remote-reading module 3 and the cover 4.

This natural flow of air is represented in FIG. 4 by arrows.

Once the cover 4 is mounted on the module 3, the covering wall 4A and the rim 4B of the cover are spaced apart from the front wall 3A and from the side wall 3B respectively of the remote-reading module. It is this spacing that enables air to flow, the air entering between the rim 4B of the cover and the side wall 3B of the remote-reading module, and leaving via the slots 4C that are present in the covering wall 4A of the cover.

In this embodiment, the cover is secured to the remote-reading module 3. It is preferably clipped onto said module, but may equally well be adhesively-bonded or screw-fastened thereon.

FIGS. 5 to 7 show a second embodiment of the invention.

These figures show a fluid meter, more precisely a water meter, comprising a vessel 1 provided with a water inlet duct segment 1A and with a water outlet duct segment 1B, and containing a measuring chamber, e.g. having a spinner or a reciprocating piston, and a counter 2 for counting consumption. On the top face of the counter there is mounted a remote-reading module 3′ that includes a front wall 3′A and a side wall 3′D, which module is for remotely reading consumption, e.g. by detecting the movement of the indicator disk of the counter in optical, capacitive, inductive, or other manner.

The invention relates to protecting the module 3′ that is of a type other than the type described above.

The module 3′ completely covers the top or front face of the counter 2, and includes openings 3′C through which it is possible to view and to read information that is carried by the top face of the counter 2, such as a specification bar code and the consumption data of a display.

In order to protect the module 3′, a specific solar radiation protective cover 4′ is used.

The cover 4′ is disposed on the casing of the module 3′ and is secured thereto, and includes a covering wall 4′A for covering the front wall 3′A of the module, and a peripheral rim 4′B that co-operates with an outwardly-directed peripheral flange 3′D that is carried by the module 3′. Once secured, the cover 4′ thus co-operates with the flange 3′D to form a kind of empty case above the module.

In its covering wall 4′A, the cover includes slots 4′C that constitute air-flow means for enabling air to flow naturally between the remote-reading module 3′ and the cover 4′.

This natural flow of air is represented in FIG. 7 by arrows.

Once the cover 4′ is mounted on the module 3′, the covering wall 4′A is thus spaced apart from the front wall 3′A of the remote-reading module, as a result of the rim 4′B being superposed on the flange 3′D. It is this spacing that enables air to flow, the air entering via the openings 3′C of the remote-reading module, and leaving via the slots 4′C that are present in the covering wall 4′A of the cover.

In this embodiment, the cover is hinged onto the remote-reading module 3′, so as to be capable of being raised, as shown in FIGS. 6A and 6B.

In order to do this, as shown in particular in FIGS. 5B and 6B, the cover 4′ is connected to the peripheral flange 3′D of the module via a hinge 5 that includes a return spring 5A for returning into the closed active position on the module. On the peripheral flange 3′D, opposite the hinge 5, there is provided a clipping arrangement 6 that co-operates with a complementary arrangement carried by the peripheral rim 4′B of the cover, so as to hold the cover in the closed active position.

Such hinging of the cover is particularly, but not exclusively, applicable when the module is of the above-described second type, so as to make it possible to view and to read information that is carried by the top face of the counter 2, such as a specification bar code and the consumption data of a display.

FIG. 8 shows a relay 10 for use in remotely reading the consumption of a meter, so as to ensure that data is transmitted remotely between the meter and the control station. The relay is provided with two antennas 10C, 10D.

The invention relates to protecting the remote-reading relay 10.

In order to do this, a specific solar radiation protective cover 4″ is used, as shown in FIG. 9. The cover 4″ is disposed on the casing of the relay 10 and is secured thereto, as shown in FIG. 10, and includes a covering wall 4″A for covering the front wall 10A of the relay, and a peripheral rim 4″B for covering the side wall 10B of the module, at least in part.

In its covering wall 4″A, the cover includes slots 4″C that constitute air-flow means for enabling air to flow naturally between the relay 10 and the cover 4″.

This natural flow of air is represented in FIG. 10 by arrows.

Once the cover 4″ is mounted on the relay 10, the covering wall 4″A and the rim 4″B of the cover are spaced apart from the front wall 10A and from the side wall 10B respectively of the relay. It is this spacing that enables air to flow, the air entering between the rim 4″B of the cover and the side wall 10B of the relay, and leaving via the slots 4″C that are present in the covering wall 4″A of the cover.

In this embodiment, the cover is secured to the remote-reading relay 10. It is preferably clipped onto said relay, but may equally well be adhesively-bonded or screw-fastened thereon.

1-14. (canceled)

15. A remote-reading device for enabling the consumption of a meter to be read remotely and including a casing with a front wall and a side wall, the device being characterized in that it also includes a specific solar radiation protective cover, said cover being disposed on the casing of the remote-reading device and including at least one covering wall for covering said front wall, the cover being secured to the casing of the remote-reading device.

16. A device according to claim 15, characterized in that said cover includes air-flow means for enabling air to flow between said remote-reading device and said cover.

17. A device according to claim 16, characterized in that said flow of air is natural.

18. A device according to claim 15, characterized in that said covering wall is spaced apart from said front wall, the cover being disposed on the device.

19. A device according to claim 15, characterized in that said cover includes orifices in said covering wall.

20. A device according to claim 15, characterized in that said cover also includes a peripheral rim.

21. A device according to claim 20, characterized in that said rim covers the side wall of said remote-reading device, at least in part.

22. A device according to claim 20, characterized in that said rim is spaced apart from said side wall of the remote-reading device, the cover being disposed on the device.

23. A device according to claim 20, characterized in that said peripheral rim co-operates with an outwardly-directed peripheral flange that is carried by the device, the cover being disposed on the device.

24. A device according to claim 15, characterized in that said cover is secured to the remote-reading device.

25. A device according to claim 15, characterized in that said cover is clipped onto the remote-reading device.

26. A device according to claim 15, characterized in that said cover is hinged onto the remote-reading device so as to be capable of being raised.

27. A remote-reading module according to claim 15 and that is installed on a meter.

28. A remote-transmission relay according to claim 15.
